(19) United States
(12) Patent Application Publication
(10) Pub. No.: US 2007/0018322 A1
(43) Pub. Date: Jan. 25, 2007

(54) Wafer level package and its manufacturing method

(75) Inventors: In Bae Park, Seoul (KR); Won Chul Do, Seoul (KR); Seong Min Seo, Seoul (KR)

Correspondence Address: Serge J. Hodgson;Gunnison, McKay & Hodgson, L.L.P., 1900 Garden Road, Suite 220, Monterey, CA, 93940, US

(73) Assignee: Amkor Technology, Inc.

(21) Appl. No.: 10/876,196

(22) Filed: Jun. 23, 2004

(51) Int. Cl. H01L 23/48

(52) U.S. Cl. 257/738; 257/779; 257/780

(57) ABSTRACT

A semiconductor package includes a semiconductor die having a plurality of bond pads, a first protective layer formed at the periphery of the bond pads of the semiconductor die, UBM (Under Bump Metals) formed at the bond pads of the semiconductor die, a plurality of solder balls wetted to the UBM, and a second protective layer formed at the periphery of the solder balls. The second protective layer includes a thick collar, which is formed from the surface of the solder ball toward its periphery, so that the joint force of the solder ball can be more improved. Further, the second protective layer protects the surface of the wafer from the external environment, and absorbs and alleviates the external stress.

### BACKGROUND OF THE INVENTION

1. Field of the Invention

The field of the present invention is related to a wafer level package and its manufacturing method.

2. Description of Related Art

Generally, a wafer level package is completely packaged in a wafer condition, so that it can reduce the size of the package as the real die size and maximize the productivity thereof.

The wafer level package includes a semiconductor die having a plurality of bond pads, an UBM (Under Bump Metallurgy) formed on the bond pads of the semiconductor die, a plurality of solder balls wetted to the UBM, and a protective layer having a uniform thickness such as BCB (Benzo Cyclo Butene) at the periphery of the solder balls.

Also, in the method for manufacturing the wafer level package, the UBM is formed at the semiconductor die of the wafer and then, the protective layer such as the BCB of a predetermined thickness is formed at the periphery thereof by a photo etching process. Finally, after the solder balls are wetted to the UBM, the wafer is sawed, thereby separating the wafer level package into individual pieces.

However, in the conventional wafer level package and its manufacturing method, since the protective layer such as the expensive BCB must be separately formed, the cost of the package becomes high as well as the complicated process, such as a coating process, an align process, an exposure process and a develop process and so on is indispensably required due to the photo etching process.

Also, in the conventional wafer level package and its manufacturing method, because the solder balls are simply wetted to the UBM, where the solder balls are mounted on an external device, there is a problem in that the solder balls can be easily separated from the wafer level package on account of the difference of the CTE (Coefficients of Thermal Expansion) by means of the thermal cycling.

In order to solve the separation problem of the solder ball, a method of forming a collar or a ring at the periphery of the solder ball has been proposed. However, in this case, since the collar or ring forming process is separately added, the cost of the package is more increased and the manufacturing process of the package is more complicated.

### SUMMARY OF THE INVENTION

In accordance with one embodiment of the present invention, a semiconductor package includes a semiconductor die having a plurality of bond pads, a first protective layer formed at the periphery of the bond pads of the semiconductor die, Under Bump Metals (UBM) formed at the bond pads of the semiconductor die, a plurality of solder balls wetted to the UBM, and a second protective layer formed at the periphery of the solder balls. The second protective layer includes a thick collar, which is formed from the surface of the solder ball toward its periphery, so that the joint force of the solder ball can be more improved. Further, the second protective layer protects the surface of the wafer from the external environment, and absorbs and alleviates the external stress.

The present invention is best understood by reference to the following detailed description when read in conjunction with the accompanying drawings.

### BRIEF DESCRIPTION OF THE DRAWINGS

FIG. 1A is a sectional view of a wafer level package according to one embodiment of the present invention; FIG. 1B is an enlarged sectional view of a part 1 of FIG. 1A;

FIG. 2 is a flow chart for explaining the method for manufacturing a wafer level package according to one embodiment of the present invention; and

FIG. 3A, 3B, 3C, 3D, 3D1, 3E, 3F, 3G, and 3H are process flows showing a manufacturing condition corresponding to each operation of FIG. 2.

Common reference numerals are used throughout the drawings and detailed descriptions to indicate the same or similar elements.

### DETAILED DESCRIPTION

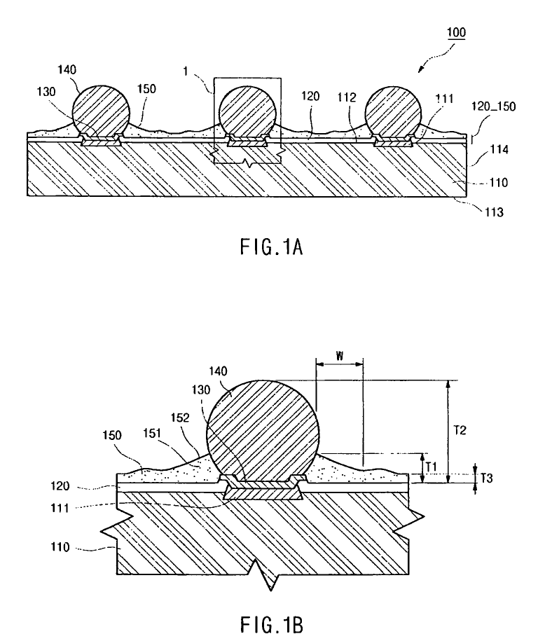

Referring to FIG. 1A, a sectional view of a wafer level package 100 according to one embodiment of the present invention is illustrated. Referring to FIG. 1B, a sectional view of a part 1 of FIG. 1A is illustrated.

As shown, the wafer level package 100 according to an embodiment of the present invention includes a semiconductor die 110 having a plurality of bond pads 111, a first protective layer 120 formed at the periphery of the bond pads 111 of the semiconductor die 110, Under Bump Metallurgy, sometimes called Under Bump Metals, (UBM) 130 formed on the bond pads 111 of the semiconductor die 110, a plurality of solder balls 140 wetted to the UBM 130, and a second protective layer 150 formed at the periphery of the solder balls 140, so as to strengthen the joint force of the solder ball 140, protect the surface of the semiconductor die 110 and buffer the stress.

The semiconductor die 110 includes an approximately planar first surface 112 having the plurality of bond pads 111, e.g., aluminum (Al), thereon and an approximately planar second surface 113 opposed to the first surface 112. Active elements or passive elements, such as a transistor, a capacitor, a diode, a resistor and the like are formed on the first surface 112. Also, the semiconductor die 110 further includes an approximately planar third surface 114 perpendicular to the first and second surfaces 112 and 113 between them.

The first protective layer 120 is formed at the entire of the first surface 112, which is located at the periphery of the bond pads 111 of the semiconductor die 110. The first protective layer 120 serves to protect the active elements or the passive elements formed on the first surface 112 from an external environment. The material of the first protective layer 120 may be a silicon dioxide, a silicon nitride or its equivalent. However, embodiments in accordance with the present invention are not limited to any material of the protective layer.

The UBM 130 is connected to the bond pad 111 of the semiconductor die 110. The UBM 130 is formed at only the bond pad 111 in drawings. However, the UBM 130 is formed at the first protective layer 120, which is located at the periphery of the bond pad 111, in a redistribution circuit pattern. The material of the UBM 130 may be a titanium (Ti), a titanium tungsten (TiW), a chromium (Cr), an aluminum (Al), a copper (Cu), a nickel (Ni) or its equivalent. However, embodiments in accordance with the present invention are not limited to any material of the UBM.

The solder balls 140 are wetted to the UBM 130. The solder balls 140 serve to transmit the electrical signals of the semiconductor die 110 to an external device (not shown) or transmit the electrical signals of the external device to the semiconductor die 110.

The second protective layer 150 is opaquely formed at the entire of the first protective layer 120, which is located at the periphery of the solder balls 140. The material of the second protective layer 150 is a polymer for protective layer. Especially, the second protective layer 150 may be a material having a function as a flux in the solder ball reflowing process or its equivalent. However, embodiments in accordance with the present invention are not limited to any material of the second protective layer. Also, the second protective layer 150 further includes a collar (or ring) 151 for covering a part of the solder ball 140. The collar 151 has a slanting surface 152, which is downwardly slanted to the periphery thereof. That is, a thickness T1 of the second protective layer 150 is gradually thin from the surface of the solder ball 140 toward the periphery thereof. More concretely, it is suitable that the width (W) of the slanting surface 152 of the second protective layer 150 is 10%-90% of the thickness T2 of the solder ball 140. Also, the second protective layer 150 has a maximum thickness T1 between the first protective layer 120 and the bonded surface of the solder ball 140. It is suitable that the maximum thickness T1 is 10%-50% of the thickness T2 of the solder ball 140. The solder ball 140 is strongly bonded to the UBM 130 on account of the collar 151 having the width W and the maximum thickness T1. Moreover, the second protective layer 150 has a minimum thickness T3 at the periphery thereof. It is suitable that the minimum thickness T3 is 10%-30% of the thickness T2 of the solder ball 140. Accordingly, since the second protective layer 150 having the minimum thickness T3 and the maximum thickness T1 is opaquely formed at the entire of the first protective layer 120, it can prevent the interference and the reflection of light and so on. Here, the second protective layer 150 protects the semiconductor die 110 from the external environment, and absorbs and alleviates the external stress.

More particularly, collar 151 has a first thickness T1 where collar 151 contacts solder ball 140. Collar has a second thickness T3 at a periphery of collar 151 spaced apart from solder ball 140 by a distance (width) W. First thickness T1 is greater than second thickness T3. Collar 151 has a slanted surface 152 extending from solder ball 140 to the periphery of collar 151.

In the meantime, since the end of the first protective layer 120 and the end of the second protective layer 150, collectively end 120_150, are flush with the third surface 114 of the semiconductor die 110, the width of the wafer level package according to an embodiment of the present invention is essentially the same as that of the semiconductor die 110.

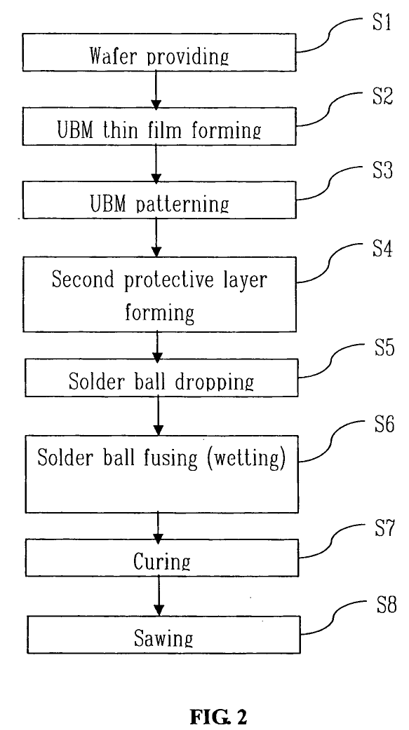

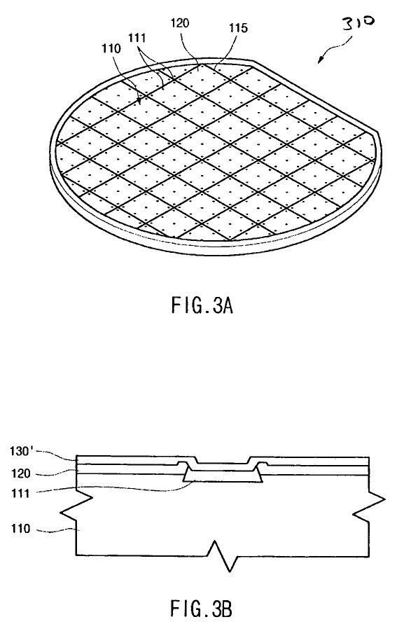

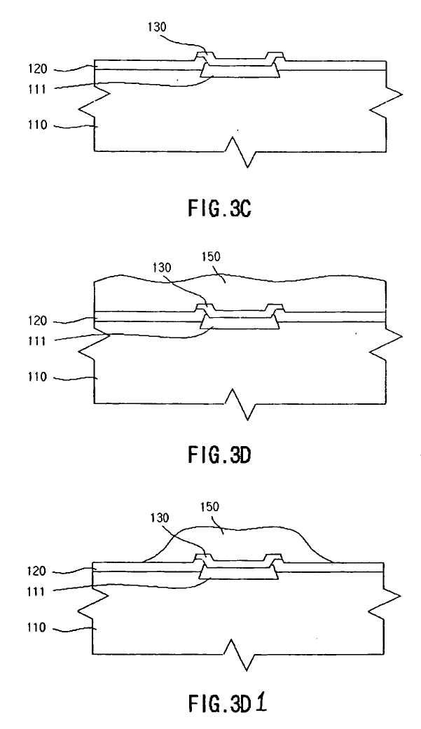

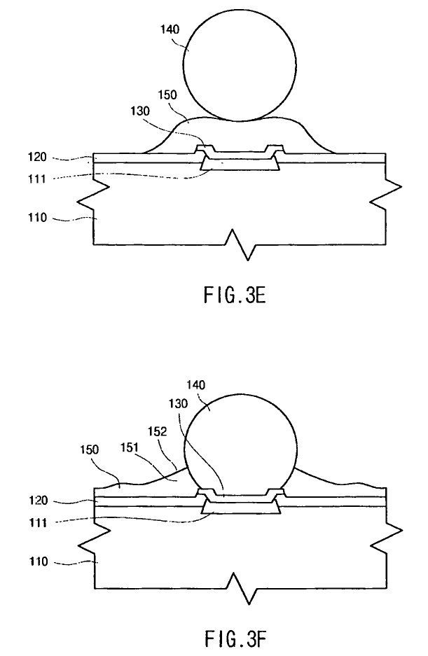

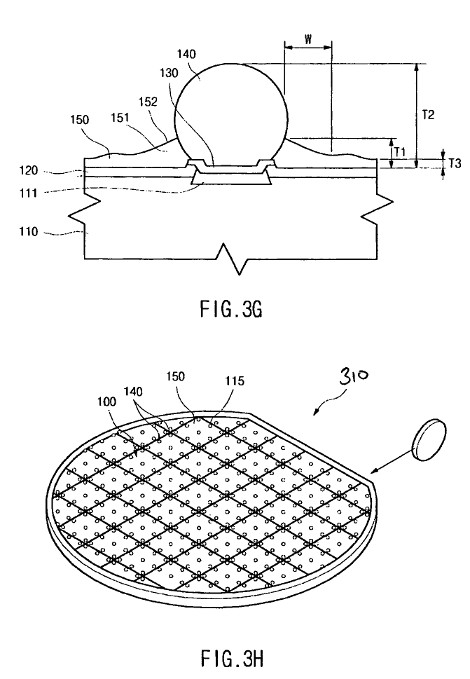

Referring to FIG. 2, a flow chart for explaining the method for manufacturing a wafer level package according to one embodiment of the present invention is illustrated. Referring to FIG. 3A through FIG. 3H, process flows showing a manufacturing condition corresponding to each operation of FIG. 2 is illustrated.

As shown, the method for manufacturing the wafer level package according to an embodiment of the present invention includes a wafer providing operation S1, an UBM thin film forming operation S2, a UBM patterning operation S3, a second protective layer forming operation S4, a solder ball dropping operation S5, the solder ball fusing operation S6, a curing operation S7, and a sawing operation S8.

In the wafer providing operation S1, the wafer 310 having a plurality of semiconductor dies 110 is provided (note FIG. 3A).

Here, a plurality of bond pads 111 is formed at the surface of a semiconductor die 110 and a first protective layer 120 such as a silicon dioxide or a silicon nitride is formed at the periphery of the bond pads 111. Also, the wafer 310 is divided into the plurality of semiconductor die along sawing lines 115, so as to separate the wafer 310 into individual pieces in the future.

In the UBM thin film forming operation S2, the UBM thin films 130 are formed at the entire top surfaces of the bond pads 111 of the wafer 310 and the first protective layer 120 (note FIG. 3B). The material of the UBM 130 may be a titanium (Ti), a titanium tungsten (TiW), a chromium (Cr), an aluminum (Al), a copper (Cu), a nickel (Ni) or its equivalent.

In the UBM patterning operation S3, the UBM 130 is patterned by using a photo etching technique, so that the UBM 130 is formed at a predetermined region connected to the bond pad 111 (note FIG. 3C).

That is, the UBM 130, which is a redistribution circuit pattern, is formed by the photo etching technique using a photo resist. Here, the UBM 130 may be formed by using a sputtering method, a evaporation method or a plating method. However, embodiments in accordance with the present invention are not limited to any method of forming the UBM.

In the second protective layer forming operation S4, a second protective layer 150 is formed at the top surface of the first protective layer 120 and the UBM 130 (note FIG. 3D).

Here, the second protective layer 150 can be uniformly formed at the entire surface of the wafer by using any one of a jetting method, a screen method and a spin coating method (note FIG. 3D). Also, the second protective layer 150 can be formed at only the circumference of the solder ball placing portion (note FIG. 3D1). The material of the second protective layer 150 may be a polymer containing a flux and an epoxy or its equivalent. At this time, in a case that the second protective layer 150 is formed at only the circumference of the solder ball placing portion, the second protective layer 150 spreads on the entire surface of the wafer in the reflowing operation.

In the solder ball dropping operation S5, a plurality of solder balls 140 is dropped on the second protective layer 150 corresponding to the UBM 130 (note FIG. 3E).

Here, the solder balls 140 can be formed in such a manner that pre-formed solder balls 140 are dropped on the second protective layer 150 corresponding to the UBM 130 by using a stencil mask, a vacuum or a solder ball bumper. However, embodiments in accordance with the present invention are not limited to any method of dropping the solder ball.

In the solder ball fusing (wetting) operation S6, the solder balls 140 are metallurgically and completely wetted to the UBM 130 at a reflow temperature while passing through the second protective layer 150 (note FIG. 3F).

At this time, the second protective layer 150 corresponding to the UBM 130 serves to prevent the solder ball 140 dropped by the flux from transferring to another position. Also, the second protective layer 150 allows the solder balls 140 to naturally placing on the UBM 130 while passing through the second protective layer 150, during fusing the solder balls. Moreover, the second protective layer 150 spreads out horizontally on account of a high temperature in the solder ball fusing operation, so that the second protective layer 150 is formed at the entire top surface of the first protective layer 120. Furthermore, the flux of the second protective layer 150 is volatilized and removed and the epoxy and others of the second protective layer 150 is solidly hardened. Also, since the thick collar 151 is formed and hardened at the region bonded to the surface of the solder ball 140, the joint force of the solder ball 140 can be more improved. Here, the second protective layer 150 protects the surface of the wafer 310 from the external environment, and absorbs and alleviates the external stress at the periphery of the collar 151.

In the curing operation S7, the solder balls 140 and the second protective layer 150 are cured and stabilized at a predetermined temperature, so that the joint force of the solder ball 140 and the adhesion strength between the first protective layer 120 and the second protective layer 150 are more improved (note FIG. 3G).

In the sawing operation S8, the wafer 310 is sawed along the sawing lines 115, thereby separating the semiconductor die 110 namely, the wafer level package into individual pieces.

This disclosure provides exemplary embodiments of the present invention. The scope of the present invention is not limited by these exemplary embodiments. Numerous variations, whether explicitly provided for or implied by the specification, such as variations in structure, dimension, type of material and the manufacturing process may be implemented by one who is skilled in the art, in view of this disclosure.

1. (canceled)

2. The wafer level package as claimed in claim 5, wherein a material of the first protective layer is selected from the group consisting of a silicon dioxide and a silicon nitride.

3. The wafer level package as claimed in claim 5, wherein a material of the second protective layer is a polymer and has a function as a flux and a collar.

4. (canceled)

5. A wafer level package comprising:
a semiconductor die comprising a first surface having a plurality of bond pads thereon, a second surface opposed to the first surface, and a third surface perpendicular to the first and second surfaces and extending between them;
a first protective layer formed at the first surface, which is located at a periphery of the bond pads of the semiconductor die;
Under Bump Metals (UBM) formed at the bond pads of the semiconductor die;
a plurality of solder balls wetted to the UBM; and
a second protective layer formed directly on an entire top surface of the first protective layer except on a portion of the first protective layer covered by the UBM, the second protective layer being located at the periphery of the solder balls, wherein the second protective layer comprises collars having slanting surfaces, which are downwardly slanted from the surfaces of the solder balls toward a periphery thereof.

6. The wafer level package as claimed in claim 5, wherein a width of the slanting surfaces of the second protective layer is 10%-90% of a thickness of the solder balls.

7. The wafer level package as claimed in claim 5, wherein a thickness of the second protective layer is gradually thin from the surfaces of the solder balls toward a periphery thereof.

8. The wafer level package as claimed in claim 5, wherein the second protective layer has a maximum thickness between the first protective layer and portions of the second protective layer bonded to the surfaces of the solder balls and the maximum thickness is 10%-50% of the thickness of the solder balls.

9. The wafer level package as claimed in claim 5, wherein the second protective layer has a minimum thickness at the periphery thereof and the minimum thickness is 10%-30% of the thickness of the solder balls.

10-15. (canceled)

16. A wafer level package comprising:
a semiconductor die comprising a first surface having a bond pad thereon;
a first protective layer formed at the first surface, the first protective layer being located at a periphery of the bond pad;
Under Bump Metals (UBM) formed at the bond pad;
a solder ball wetted to the UBM; and
a second protective layer formed directly on an entire top surface of the first protective layer except the on a portion of the first protective layer covered by the UBM, the second protective layer being located at the periphery of the solder ball, wherein the second protective layer comprises a collar covering a part of the solder ball, wherein the collar has a first thickness where the collar contacts the solder ball and has a second thickness at a periphery of the collar spaced apart from the solder ball, the first thickness being greater than the second thickness.

17. The wafer level package as claimed in claim 16, wherein the collar comprises a slanted surface.

18. The wafer level package as claimed in claim 17, wherein the slanted surface extends from the solder ball to the periphery of the collar.

19. The wafer level package as claimed in claim 16, wherein the collar becomes gradually thinner from where the collar contacts the solder ball to the periphery of the collar.

20. (canceled)

21. A wafer level package comprising:
a semiconductor die comprising a first surface having bond pads thereon, the semiconductor die being one of a plurality of semiconductor dies of a wafer;
a first protective layer formed at the first surface, the first protective layer being located at a periphery of the bond pads;
Under Bump Metals (UBM) formed at the bond pads;
solder balls wetted to the UBM; and
a second protective layer formed directly on an entire top surface of the first protective layer except on a portion of the first protective layer covered by the UBM, the second protective layer being located at the periphery of the solder balls, wherein the second protective layer comprises collars covering a part of the solder balls, wherein the collars have a first thickness where the collars contact the solder balls and have a second thickness at a periphery of the collars spaced apart from the solder balls, the first thickness being greater than the second thickness.

22. The wafer level package as claimed in claim 21, wherein the collars comprise slanted surfaces.

23. The wafer level package as claimed in claim 22, wherein the slanted surfaces extend from the solder balls to the periphery of the collars.

24. The wafer level package as claimed in claim 21, wherein the collars becomes gradually thinner from where the collars contact the solder balls to the periphery of the collars.

25. (canceled)

26. The wafer level package as claimed in claim 21, wherein the second protective layer is opaque, the second protective layer preventing the interference and reflection of light.
